(19) United States
(12) Patent Application Publication
(10) Pub. No.: US 2004/0223310 A1
(43) Pub. Date: Nov. 11, 2004

(54) Printed circuit board and apparatus using the same

(75) Inventor: Fumitaka Toyomura, Nara (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/834,039

(22) Filed: Apr. 29, 2004

(30) Foreign Application Priority Data
May 9, 2003 (JP) 2003-132159

(51) Int. Cl. H05K 7/06

(52) U.S. Cl. 361/777; 361/780; 174/262

(57) ABSTRACT

In a printed circuit board which has two layers with wiring patterns formed thereon and on which components of a booster circuit that boosts a voltage of an input power are mounted, within a plurality of wiring patterns which connect the input terminal of the input power to the terminal of a component to which the input power is supplied, patterns formed on the two layers are connected by a through hole formed near the input terminal and the terminal of the component. Accordingly, in the patterns to which a relatively large current flows upon receiving the input power, currents flowing to the patterns formed on the two layers are almost uniformed. For this reason, loss due to the wiring resistance in the patterns can be reduced.

### FIELD OF THE INVENTION

The present invention relates to a printed circuit board and, more particularly, to a printed circuit board suitable for mounting a booster circuit which boosts a voltage of an input power, for example, a DC/DC conversion circuit which uses a solar battery as an input source and receives a low-voltage large-current power.

### BACKGROUND OF THE INVENTION

As part of recent approach to environmental problems, attempts have been made to cause power conversion apparatuses to convert a DC power generated by solar batteries or fuel batteries into an AC power and supply it to domestic loads (to be referred to as a “load” hereinafter) and/or commercial power systems (to be referred to as a “system” hereinafter) or convert a DC power into a predetermined DC voltage and use it to drive loads.

Most power conversion apparatuses used for the above purposes have a function of boosting the output voltage from a solar battery to a predetermined voltage. The boosted power is used for a DC load or input to a DC/AC conversion apparatus, converted into an AC power, and then connected to a system.

There is also a method of raising the output voltage from solar batteries to a predetermined voltage by connecting the solar batteries themselves in series. However, connecting solar batteries in series requires a number of working steps and accordingly increases the cost. In addition, the non-power-generation area of the solar power generation apparatus increases, and the influence of partial shade becomes large.

To solve this problem, a solar power generation apparatus has been proposed which minimizes the number of solar batteries connected in series and boosts the output voltage from them to a high voltage, thereby extracting a high-voltage small-current output power.

An example of such a solar power generation apparatus is described in Markus Wuest, Peter Toggweiler, Jon Riatsch, “SINGLE CELL CONVERTER SYSTEM (SCCS)”, First WCPEC, Hawaii, Dec. 5-9, pp. 813-815, 1994.

In this solar power generation apparatus, only a low voltage of about 1 V can be output per solar cell (panel). Hence, a DC/DC conversion apparatus (DC/DC converter) having a high boost ratio is necessary.

Conventionally, a push-pull circuit is used as an example of the circuit scheme in a power conversion apparatus for converting a low-voltage large-current input power into a high voltage, as described above.

As an example of a power conversion apparatus which uses a push-pull circuit and has a high boost ratio, an inverter apparatus is proposed in Japanese Patent Laid-Open No. 5-308779, in which a plurality of transformers are used, the primary coils are connected in parallel, and the secondary coils are connected in series to boost a voltage.

When such a DC/DC conversion apparatus is to be connected to the above-described solar battery, the DC/DC conversion apparatus is preferably arranged immediately near the solar battery except its light-receiving region in order to reduce transmission loss-between the solar battery and the DC/DC conversion apparatus. To prevent any decrease in area power generation efficiency in a solar battery constructed as a module, the area of the projecting portion except the light-receiving region of the solar battery needs to be small. For this purpose, the width of the DC/DC conversion apparatus is required to be as small as possible.

For example, in the mounted state on a board in Japanese Patent Laid-Open No. 5-308779, it is ideal that a plurality of transformers T1 to T4 are arrayed as shown in FIG. 2 to decrease a width W of the printed circuit board and make the projecting portion except the light-receiving region of the solar battery small. Referring to FIG. 2, reference symbols Q1 and Q2 denote transistors serving as switching elements; C, a capacitor; and R, a resistor.

FIG. 3 is a view showing the pattern of input terminal portions to the circuits on this board and the pattern layout between the transformers T1 to T4 and the transistors Q1 and Q2. Reference numerals 301 and 302 denote patterns of the input terminal portions; and 303 and 304, patterns between the transformers T1 to T4 and the transistors Q1 and Q2. The pattern indicated by the dotted line is arranged on the lower surface of the printed circuit board.

The width W of the printed circuit board is further decreased in this pattern layout. In this case, since each of the transformers T1 to T4 has a predetermined size, the wiring width of each of the patterns 301 to 304 must be decreased.

However, when a solar cell is used as an input source, since the input power has a voltage as low as about 1 V and a large current that should reach about 10 A, loss in the wiring resistance in the patterns must be taken into consideration. More specifically, when the wiring widths of the patterns 301 to 304 are decreased, the wiring resistance in the patterns increases, and the conversion efficiency of the power conversion apparatus becomes low. In addition, heat generated from the patterns adversely affects the service life of semiconductor components around them.

When the above-described low-voltage large-current power is to be converted into a high voltage, the boost ratio of the DC/DC conversion apparatus must have a large value of 100 or more. Hence, when the wiring resistance in the patterns increases, and the voltage drop in the patterns becomes large, no desired high voltage can be obtained.

As a solution to prevent the increase in wiring resistance in the patterns, a thick copper foil having a thickness of, e.g., 200 μm may be used in the patterns of the printed circuit board. This increases the cost because usable printed circuit board material is limited, and the method of manufacturing the printed circuit board itself is complicated. In addition, the mounting conditions also become strict as compared to a general printed circuit board using a copper thickness of 70 μm or less.

As another solution, a pattern for wiring is formed on a surface (lower surface) different from the component-mounted surface. This pattern and the pattern on the component-mounted surface are connected by through holes to obtain a uniform current distribution. However, in a printed circuit board to which a large current flows, it is difficult to uniformly supply a current to the patterns on the two surfaces. No sufficient effect can be obtained by appropriately arraying through holes at equal intervals, as shown in FIG. 9.

### SUMMARY OF THE INVENTION

It is an object of the present invention to provide a printed circuit board capable of reducing loss by wiring resistance in patterns to which a relatively large current flows.

According to one aspect of the present invention there is provided a printed circuit board which has two layers with wiring patterns formed thereon and on which components of a booster circuit that boosts a voltage of an input power are mounted, wherein a plurality of wiring patterns which connect an input terminal of the input power to a terminal of a component to which the input power is supplied are formed, and a through hole which connects the patterns formed on the two layers is formed near the input terminal and the terminal of the component.

More specifically, in the present invention, in a printed circuit board which has two layers with wiring patterns formed thereon and on which components of a booster circuit that boosts a voltage of an input power are mounted, within a plurality of wiring patterns which connect the input terminal of the input power to the terminal of a component to which the input power is supplied, patterns formed on the two layers are connected by a through hole formed near the input terminal and the terminal of the component.

Accordingly, in the patterns to which a relatively large current flows upon receiving the input power, currents flowing to the patterns formed on the two layers are almost uniformed. For this reason, loss due to the wiring resistance in the patterns can be reduced.

The plurality of wiring patterns which connect the input terminal of the input power to the terminal of the component to which the input power is supplied, a pattern having a largest wiring length may be formed on each of the two layers in substantially the same shape.

A plurality of through holes may be formed substantially at an equal interval.

Preferably, the number of through holes is decided in accordance with a value of a current which flows to the wiring patterns.

The booster circuit may include a plurality of transformers and a plurality of switching elements.

The booster circuit may include a push-pull circuit.

Two input terminals of the input power may be arranged on one side.

The present invention can also be applied to a power conversion apparatus including the booster circuit mounted on the printed circuit board and a solar power generation apparatus which uses the power conversion apparatus and receives an input power from a solar battery.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a view schematically showing patterns on the upper surface of a printed circuit board according to the embodiment of the present invention;

FIG. 2 is a view showing an example of a printed circuit board on which a conventional push-pull circuit is mounted;

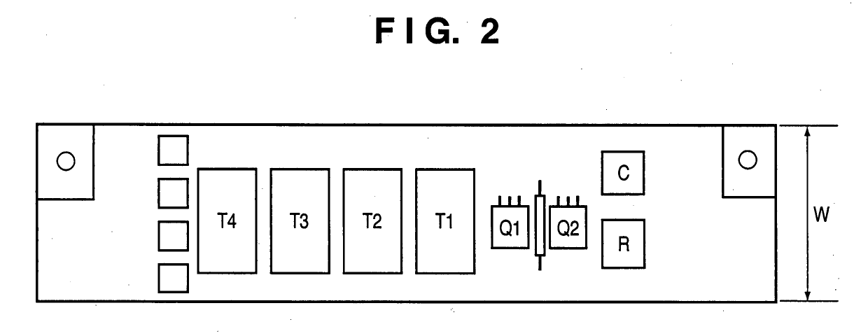

FIG. 3 is a view partially showing patterns on the printed circuit board shown in FIG. 2;

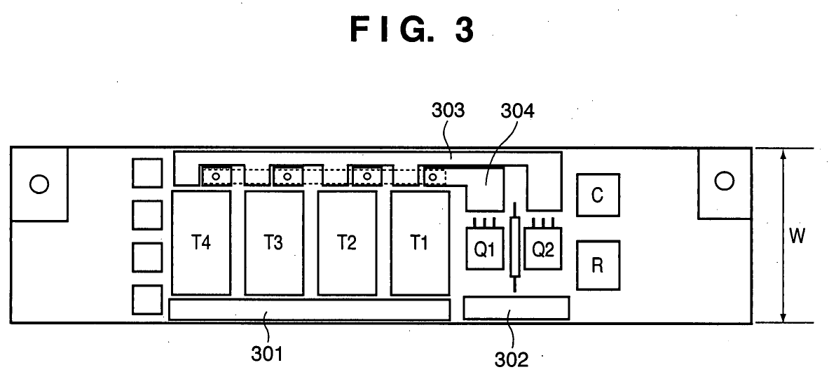

FIG. 4 is a circuit diagram showing circuits mounted on the printed circuit board shown in FIG. 1;

FIG. 5 is a view schematically showing a pattern on the lower surface of the printed circuit board shown in FIG. 1;

FIG. 6 is a view for explaining current concentration points in the printed circuit board shown in FIG. 1;

FIG. 7 is a partial enlarged view of a structure near the source electrode of a MOSFET;

FIG. 8 is a partial enlarged view of a structure near an input terminal; and

FIG. 9 is a view schematically showing patterns on the upper surface of a conventional printed circuit board.

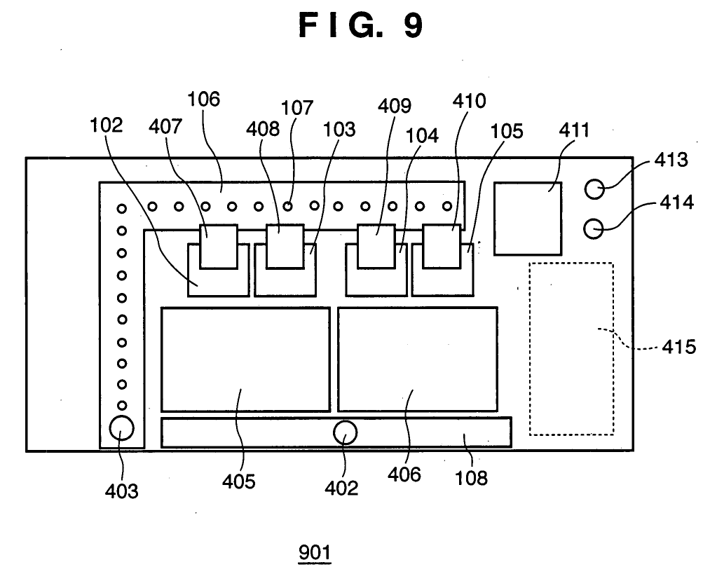

### DETAILED DESCRIPTION OF THE PREFERRED EMBODIMENTS

Preferred embodiments of the present invention will now be described in detail in accordance with the accompanying drawings.

In this specification, fixing and connecting components to a printed circuit board by soldering or the like will be referred to as “mounting”. In a wiring pattern formed on the printed circuit board, portions where a copper foil and the like, to which components and terminals are connected, are exposed will be referred to as “lands”. When components are mounted on one surface of the printed circuit board, the surface on which the components are mounted will be referred to as an “upper surface”, and the other surface will be referred to as a “lower surface”.

A printed circuit board on which a push-pull circuit is mounted will be described below as an example. However, the present invention is not limited to this example.

First, the push-pull circuit according to the present invention will be described. Next, the printed circuit board on which the push-pull circuit is to be mounted will be described in association with a manufacturing method.

(Push-Pull Circuit)

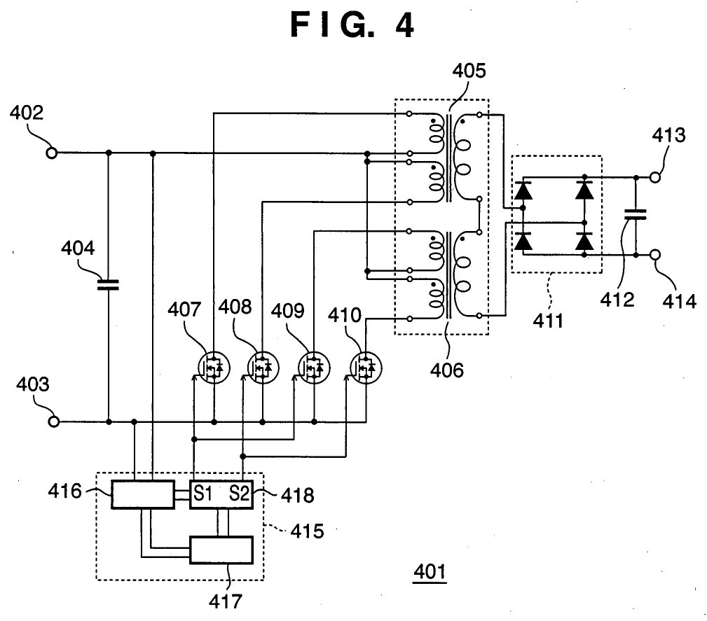

FIG. 4 is a circuit diagram of a push-pull circuit 401 according to the present invention. A DC power input from a power supply such as a solar battery to input terminals 402 and 403 is smoothed by a capacitor 404 and supplied to switching elements 407 to 410 such as MOSFETs through two transformers 405 and 406, which have input sides connected in parallel and output sides connected in series. When a solar battery is used as an input power supply, the input voltage is about 1 V. The input current sometimes becomes 10 A or more.

The input DC power is converted into an AC power by alternately turning on/off the switching elements 407 and 409 and the switching elements 408 and 410. The AC power input to the transformers 405 and 406 is boosted in accordance with the transformation ratio of the transformers and rectified and converted into a high-voltage DC power by a diode bridge 411.

The high-voltage DC power is smoothed by a capacitor 412 and supplied to a load through output terminals 413 and 414.

The operation of a control circuit 415 that controls the switching elements 407 to 410 will be described next. The control circuit 415 shown in FIG. 4 includes a control power supply unit 416, reference wave generation unit 417, and driver 418.

When the input voltage to the push-pull circuit 401 reaches a threshold voltage at which the control power supply unit 416 is activated, a power is supplied from the control power supply unit 416 to the reference wave generation unit 417 and driver 418.

The reference wave generation unit 417 generates a reference rectangular wave having a preset frequency and supplies it to the driver 418. On the basis of the reference rectangular wave, the driver 418 generates two gate driving signals S1 and S2 which alternately turn on/off the switching elements 407 and 409 and the switching elements 408 and 410, and supplies the gate driving signals S1 and S2 to the gates of the switching elements 407 to 410 to ON/OFF-control them.

In this embodiment, the switching frequency is 40 kHz and the ON/OFF duty ratio is 0.49.

(Printed circuit board)

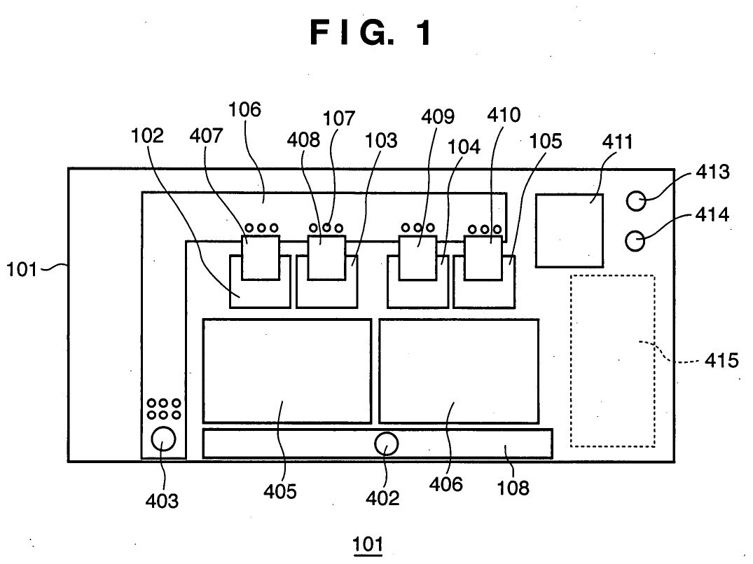

The printed circuit board on which the push-pull circuit is to be mounted will be described next. FIG. 1 is a view schematically showing patterns on the upper surface of a printed circuit board 101 according to the embodiment of the present invention, on which the push-pull circuit is to be mounted.

The base material of the printed circuit board used here is a 1.6-mm thick FR-4 material. A 70-μm thick copper foil is formed on both the upper and lower surfaces. The copper foils on both surfaces are selectively melted by etching or the like to form patterns. Portions other than lands to which components are to be connected are covered with a resist material.

The board material, board thickness, and copper thickness used in the present invention are not limited to the above examples, and various materials and thicknesses can be used.

The lands 402 and 403 for the two input terminals are formed near the edge of one side of the printed circuit board 101 so that loss due to the wiring resistance is minimized, and connection to a power supply such as a solar battery can easily be done. The land 402 for the input terminal is formed on a pattern 108 to which the primary coils of the transformers 405 and 406 are to be connected. Markers for the lands 402 and 403 for the input terminals are preferably formed on the board by silk printing.

The lands 402 and 403 may have through holes having sizes capable of directly receiving lead terminals from the power supply.

The transformers 405 and 406 are arranged such that two long sides of the two transformers are arranged in a line in consideration of input of a large current and reduction of a width W of the printed circuit board. The primary coils of the transformers are connected to the land 402 for the input terminal through the pattern 108.

The detailed structure of the transformer used in this embodiment is irrelevant to the gist of the present invention, and a detailed description thereof will be omitted.

Terminals of the primary coils of the transformers 405 and 406, on the opposite side of the terminals connected to the input terminals, are connected to patterns 102 to 105, respectively.

The MOSFETs 407 to 410 used in this embodiment are SO-8 packages each having four terminals arranged on each side. The drain electrodes are connected to the patterns 102 to 105, respectively. The source electrodes of all the MOSFETs are connected to a pattern 106.

Mounted states of the capacitors 404 and 412 are irrelevant to the present invention, and a description thereof will be omitted.

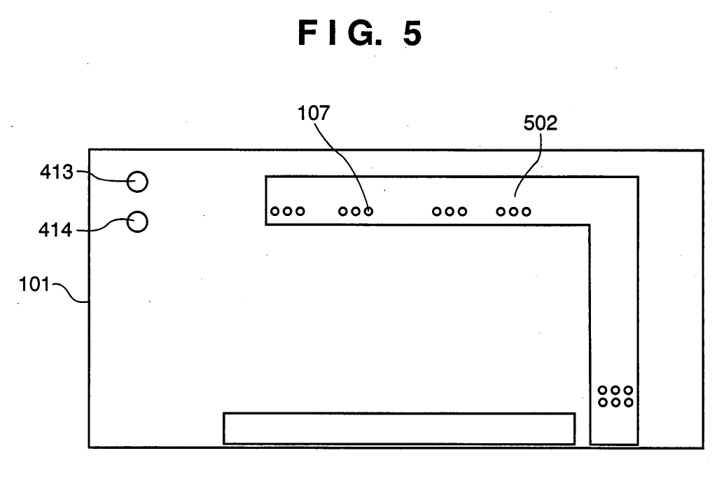

FIG. 5 is a view showing a pattern on the lower surface of the printed circuit board 101 of this embodiment. As shown in FIG. 5, a pattern 502 having almost the same shape as the inverted shape of the pattern 106 on the upper surface is formed on the lower surface of the printed circuit board 101. The patterns on the upper and lower surfaces are connected by through holes 107. Accordingly, the current that flows between the source electrodes of the MOSFETs and the input terminal 403 can almost uniformly be distributed on the upper and lower surfaces. Hence, loss due to the wiring resistance in the current channel can be minimized.

The pattern 106 in FIG. 1 and the pattern 502 in FIG. 5 are preferably narrow. The power consumed by the patterns must be decreased while minimizing their widths.

As a characteristic feature of the present invention, the through holes are laid out only at the current concentration points. The through hole layout in this embodiment will be described below in detail.

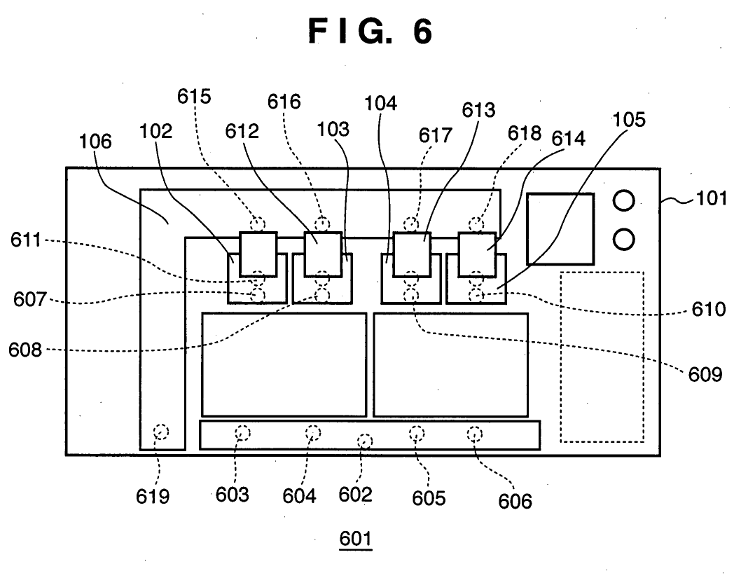

FIG. 6 is a view for explaining the current concentration points in the board 101.

In this specification, a current concentration point means a region (connection point) at which a terminal or element is connected to the printed circuit board by soldering or the like.

Hence, as indicated by points surrounded by broken lines in FIG. 6, current concentration points in this embodiment include a connection point 602 between the input terminal land 402 and the pattern 108, connection points 603 to 606 between the pattern 108 and the primary coils of the transformers, connection points 607 to 610 each between a corresponding one of the patterns 102 to 105 and the other terminal of a corresponding one of the primary coils of the transformers, connection points 611 to 614 between the patterns 102 to 105 and the drain electrodes of the MOSFETs, connection points 615 to 618 between the pattern 106 and the source electrodes of the MOSFETs and a connection point 619 between the input terminal land 403 and the pattern 106.

When through holes are formed near the current concentration points, the current flowing to the pattern on the surface (lower surface) different from the component-mounted surface and that flowing to the pattern on the upper surface can almost be uniformed, and loss due to the wiring resistance in the patterns can be reduced.

In the printed circuit board of this embodiment, in the pattern 106 that connects the source electrodes of the MOSFETs to the input terminal land 403, the flowing current is large, and the wiring length is large. Hence, when the pattern 502 is also formed on the lower surface, as shown in FIG. 5, to uniform the currents flowing to the upper and lower surfaces, a large effect can be obtained.

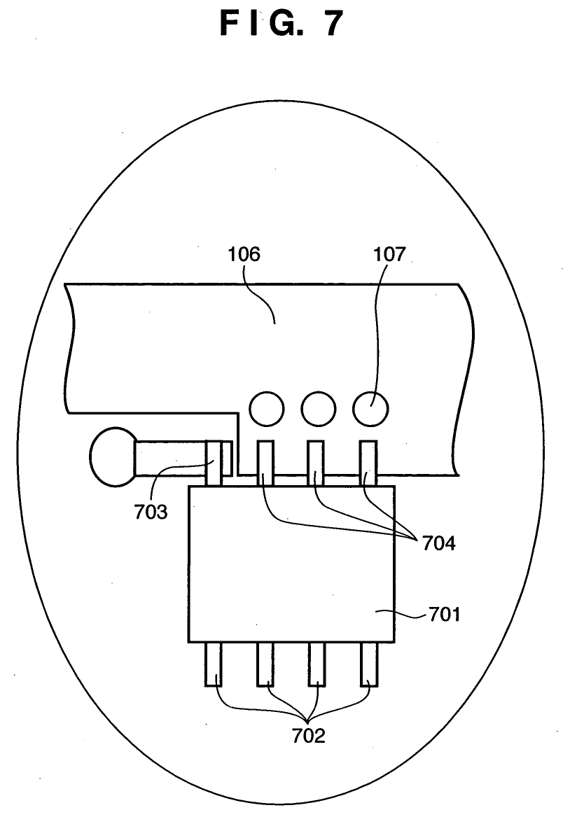

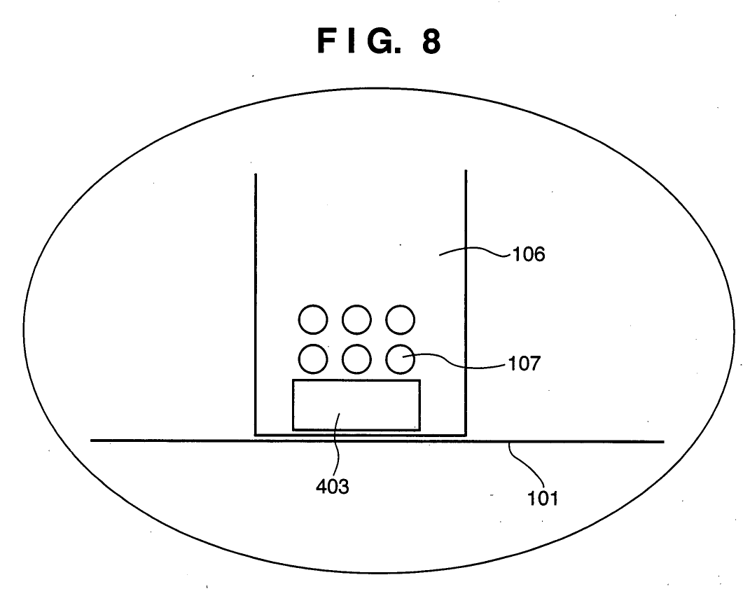

The through holes formed in this embodiment will be described here in detail with reference to FIGS. 7 and 8. FIG. 7 is an enlarged view of a structure near the connection portion between the source electrode of a MOSFET and the pattern 106. FIG. 8 is an enlarged view of a structure near the connection portion between the input terminal land 403 and the pattern 106.

Referring to FIG. 7, reference numeral 701 denotes a MOSFET; and 702, 703, and 704, drain electrodes, a gate electrode, and source electrodes of the MOSFET 701, respectively. As shown in FIG. 7, the three through holes 107 are formed near the lands to which the terminals of the three source electrodes of the MOSFET are connected. In this embodiment, the through hole has a diameter of 0.5 mm, and the distance between the land and the through hole is 0.5 mm.

The through hole is preferably formed at a position where the distance between the terminal (or the land connected to the terminal) of the source electrode and the through hole becomes equal to or smaller than the diameter of the through hole. When a plurality of through holes are to be formed, the distance between them is preferably equal to or smaller than the diameter of the through hole.

When the through holes are formed in this way, they are arranged near the current concentration points. The current from the source electrode immediately uniformly branches to the patterns on the upper and lower surfaces.

For the input terminal land 403 shown in FIG. 8, two rows of three through holes, i.e., a total of six through holes each having a size of φ1 mm are formed at positions separated from the land by 0.5 mm. The distance between the through holes is 0.5 mm.

The through hole used in this embodiment is formed in the following way. A hole having a desired diameter is formed by using a drill. The resultant structure is cleaned and metallized by electroless copper plating. Then, a 25-μm thick copper film is formed by electroplating of copper.

The number of through holes formed at each current concentration point is not particularly limited as long as at least one through hole is formed. The number of through holes is preferably small from the viewpoint of the strength and cost of the board. For this reason, the number of through holes to be formed is preferably decided in accordance with the value of the current that should flow to that portion. The size of the through hole is also preferably decided in consideration of the value of the current that should flow to that portion.

As described above, according to this embodiment, the through holes that connect the wiring patterns on the component-mounted surface and the other surface (lower surface) are formed at the current concentration points. Accordingly, the current can almost uniformly be supplied to the two surfaces, and loss due to the wiring resistance can be reduced.

In the push-pull circuit as in this embodiment, the portion between the source electrode of a MOSFET and the input terminal (input terminal land) readily becomes long particularly on the board. At this portion, a voltage drop due to the wiring resistance readily occurs. When the present invention is applied to such a portion, the voltage drop can be decreased. Hence, the present invention can particularly effectively be applied to a printed circuit board on which a DC/DC conversion apparatus which has a high boost ratio and uses a power supply such as a solar battery with a low input voltage is to be mounted.

As described above, according to this embodiment, an especially large effect can be obtained by applying the present invention to a portion with a large pattern length (wiring length) between current concentration points at equipotential, i.e., a portion having a high wiring resistance.

<Other Embodiment>

In the above-described embodiment, a printed circuit board on which a push-pull circuit is mounted has been exemplified. However, the present invention is not limited to this and can also be applied to a printed circuit board on which another known circuit is mounted.

In this embodiment, a double-sided board is used, and the layout of through holes that connect wirings on the component surface and the lower surface has been described. When a multilayered board is used as the printed circuit board, the same effect as described above can be expected by applying the present invention to via holes that connect the respective layers.

The present invention can be applied to either a printed circuit board on which one circuit is mounted or a system formed from a plurality of devices (e.g., a power conversion apparatus, solar battery, fuel battery, control circuit, and the like) including circuits mounted on the printed circuit board.

As many apparently widely different embodiments of the present invention can be made without departing from the spirit and scope thereof, it is to be understood that the invention is not limited to the specific embodiments thereof except as defined in the appended claims.

What is claimed is:

1. A printed circuit board which has two layers with wiring patterns formed thereon and on which components of a booster circuit that boosts a voltage of an input power are mounted,
wherein a plurality of wiring patterns which connect an input terminal of the input power to a terminal of a component to which the input power is supplied are formed, and
a through hole which connects the patterns formed on the two layers is formed near the input terminal and the terminal of the component.

2. The board according to claim 1, wherein the plurality of wiring patterns which connect the input terminal of the input power to the terminal of the component to which the input power is supplied, a pattern having a largest wiring length is formed on each of the two layers in substantially the same shape.

3. The board according to claim 1, wherein a plurality of through holes are formed substantially at an equal interval.

4. The board according to claim 1, wherein the number of through holes is decided in accordance with a value of a current which flows to the wiring patterns.

5. The board according to claim 1, wherein the booster circuit includes a plurality of transformers and a plurality of switching elements.

6. The board according to claim 1, wherein the booster circuit includes a push-pull circuit.

7. The board according to claim 1, wherein two input terminals of the input power are arranged on one side.

8. A power conversion apparatus including a booster circuit which is mounted on a printed circuit board having two layers with wiring patterns formed thereon and boosts a voltage of an input power,
said booster circuit being configured such that a plurality of wiring patterns which connect an input terminal of the input power to a terminal of a component to which the input power is supplied are formed on the printed circuit board, and
a through hole which connects the patterns formed on the two layers is formed near the input terminal and the terminal of the component.

9. A solar power generation apparatus which uses a power conversion apparatus including a booster circuit and receives an input power from a solar battery, the booster circuit being mounted on a printed circuit board having two layers with wiring patterns formed thereon and boosting a voltage of an input power,
said booster circuit being configured such that a plurality of wiring patterns which connect an input terminal of the input power to a terminal of a component to which the input power is supplied are formed on the printed circuit board, and
a through hole which connects the patterns formed on the two layers is formed near the input terminal and the terminal of the component.
